(19) United States
(12) Patent Application Publication
(10) Pub. No.: US 2025/0143021 A1
(43) Pub. Date: May 1, 2025

(54) LIGHT-EMITTING DIODE AND LIGHT-EMITTING DEVICE

(71) Applicant: XIAMEN SAN'AN OPTOELECTRONICS CO., LTD., Xiamen (CN)

(72) Inventors: BIN JIANG, Xiamen (CN); SIHE CHEN, Xiamen (CN); GONG CHEN, Xiamen (CN); YASHU ZANG, Xiamen (CN); CHUNG-YING CHANG, Xiamen (CN); KANG-WEI PENG, Xiamen (CN); WEICHUN TSENG, Xiamen (CN); MINGCHUN TSENG, Xiamen (CN); SIYI LONG, Xiamen (CN)

(21) Appl. No.: 19/008,709

(22) Filed: Jan. 3, 2025

Related U.S. Application Data
(63) Continuation of application No. PCT/CN2022/103613, filed on Jul. 4, 2022.

(51) Int. Cl. H10H 20/816; H10H 20/81; H10H 20/819; H10H 20/825

(52) U.S. Cl. CPC H10H 20/8162; H10H 20/819; H10H 20/8215; H10H 20/825

(57) ABSTRACT

A light-emitting diode includes a semiconductor layer sequence. The semiconductor layer sequence includes a first semiconductor layer, a second semiconductor layer and an active layer, and further includes a first mesa and a second mesa. The first mesa has a current blocking structure adjacent to the second mesa and a current conduction portion located below the current blocking structure. The first semiconductor has a first surface facing away from the active layer, the first mesa is provided with a second surface facing away from the first surface, a distance between the second surface and the first surface is greater than or equal to a half of a thickness of the first semiconductor layer, and the current conduction portion has a height in a thickness direction of the semiconductor layer sequence being ⅕ to ½ of the thickness of the first semiconductor layer. The light-emitting diode can improve carrier injection efficiency.

### CROSS-REFERENCE TO RELATED APPLICATION

This application is a continuation of International Application No. PCT/CN2022/103613, filed Jul. 4, 2022, which is herein incorporated by reference in its entirety.

### TECHNICAL FIELD

The disclosure relates to the field of semiconductor technologies, and more particularly to a light-emitting diode and a light-emitting device.

### BACKGROUND

Semiconductor devices, including compounds such as gallium nitride (GaN) and aluminum gallium nitride (AlGaN), have many advantages such as a wide and easily adjustable bandgap energy, and can be variously used as light-emitting devices, light-receiving devices, various diodes, etc.

In recent years, a significant application value of ultraviolet (UV) light-emitting diodes (LEDs), especially deep-ultraviolet (DUV) LEDs, has attracted great attention and become a new research hotspot. UV LEDs utilize group-III-nitride semiconductor materials containing aluminum (Al). However, a high resistivity of nitride semiconductors containing Al leads to low carrier injection efficiency when used in n-type semiconductor layers.

### SUMMARY

One of the objectives of the disclosure is to provide a light-emitting diode and a light-emitting device that can effectively enhance carrier injection efficiency of the light-emitting diode.

In some embodiments, the disclosure provides a light-emitting diode, which includes a semiconductor layer sequence, a first electrode, and a second electrode.

The semiconductor layer sequence includes a first semiconductor layer with a first conductive type, a second semiconductor layer with a second conductive type different from the first conductive type, and an active layer disposed between the first semiconductor layer and the second semiconductor layer. The semiconductor layer sequence further includes a first mesa and a second mesa located above the first mesa, the first mesa has a current blocking structure adjacent to the second mesa and a current conduction portion located below the current blocking structure, and the second mesa functions as a light-emitting mesa.

The first electrode is formed on the first mesa and electrically connected to the first semiconductor layer.

The second electrode is formed on the second mesa and electrically connected to the second semiconductor layer.

The first semiconductor layer is an n-type doped AlGaN semiconductor layer, providing a first surface facing away from the active layer, the first mesa is provided with a second surface facing away from the first surface, a distance between the second surface and the first surface is greater than or equal to a half of a thickness of the first semiconductor layer, and the current conduction portion has a height in a thickness direction of the semiconductor layer sequence being ⅕ to ½ of the thickness of the first semiconductor layer.

In other embodiments, the light-emitting diode includes the semiconductor layer sequence, the first electrode, and the second electrode.

The semiconductor layer sequence includes the first semiconductor layer with the first conductive type, the second semiconductor layer with the second conductive type different from the first conductive type, and the active layer disposed between the first semiconductor layer and the second semiconductor layer. The semiconductor layer sequence further includes the first mesa and the second mesa located above the first mesa, the first mesa has the current blocking structure adjacent to the second mesa and the current conduction portion located below the current blocking structure, and the second mesa is the light-emitting mesa.

The first electrode is formed on the first mesa and electrically connected to the first semiconductor layer.

The second electrode is formed on the second mesa and electrically connected to the second semiconductor layer.

The first semiconductor layer includes a first sub-layer with a first doping concentration and a second sub-layer with a second doping concentration, and the first doping concentration is greater than the second doping concentration. The second surface is located on the first sub-layer, the first electrode is in direct contact with the first sub-layer, and the current conduction portion is located in the second sub-layer.

In the light-emitting diode of the disclosure, the semiconductor layer sequence is provided with the first mesa and the second mesa. The first electrode is disposed on the first mesa, the second electrode is disposed on the second mesa, and the current blocking structure is disposed between the first mesa and the second mesa, which can prevent injected current from directly diffusing to the active layer on the second mesa and instead cause the injected current to expand downward due to being blocked by the current blocking structure. Furthermore, the distance between the second surface and the first surface is greater than or equal to the half of the thickness of the first semiconductor layer, thereby mobilizing carriers below to participate in a movement, allowing more carriers in the n-type AlGaN semiconductor layer to be effectively utilized, and thus enhancing the carrier injection efficiency.

In some embodiments, the current blocking structure is specifically spaced apart from the second mesa to avoid damage to the second mesa.

In some embodiments, different doping concentrations can be combined with the current blocking structure to accommodate applications requiring both contact (high concentration) and expansion (low concentration).

In some embodiments, the first semiconductor layer includes at least the first sub-layer with the first doping concentration and the second sub-layer with the second doping concentration. The first electrode is in direct contact with the first sub-layer, the current conduction portion is located in the second sub-layer, and the first doping concentration is greater than the second doping concentration. By setting different doping concentrations in combination with the current blocking structure, a contact voltage between the first semiconductor layer and the first electrode can be reduced, and an expansion capability of the first semiconductor layer can be improved.

### BRIEF DESCRIPTION OF DRAWINGS

FIG. 1A illustrates a cross-sectional view of a light-emitting diode according to an illustrated embodiment of the disclosure.

FIG. 1B illustrates a cross-sectional view of a light-emitting diode according to another illustrated embodiment of the disclosure.

FIG. 1C illustrates a cross-sectional view of a light-emitting diode according to still another illustrated embodiment of the disclosure.

FIG. 1D illustrates a cross-sectional view of a light-emitting diode according to even still another illustrated embodiment of the disclosure.

FIG. 2 illustrates a top view of the light-emitting diode according to the illustrated embodiment of the disclosure.

FIG. 3 illustrates a top view of a semiconductor layer sequence according to the illustrated embodiment of the disclosure.

FIG. 4 illustrates a top view of a current blocking structure according to the illustrated embodiment of the disclosure.

FIG. 5 illustrates a partial enlarged view of A region shown in FIG. 4.

FIG. 6 illustrates a top view of a current blocking structure according to another illustrated embodiment of the disclosure.

FIG. 7 illustrates a partial enlarged view of B region shown in FIG. 6.

FIG. 8 illustrates a cross-sectional view of a light-emitting diode according to an illustrated embodiment of the disclosure.

FIG. 9 illustrates a light output power (LOP) distribution map (also referred to as LOP mapping) of different samples.

FIG. 10 illustrates a cross-sectional view of a light-emitting diode according to an illustrated embodiment of the disclosure.

FIG. 11 illustrates a cross-sectional view of a light-emitting diode according to an illustrated embodiment of the disclosure.

FIG. 12 illustrates a cross-sectional view of a light-emitting device according to an illustrated embodiment of the disclosure.

### DETAILED DESCRIPTION OF EMBODIMENTS

According to illustrated embodiments of the disclosure, a light-emitting diode can emit light within an ultraviolet (UV) wavelength range. For example, the light-emitting diode can emit light within a near UV (UV-A) wavelength range, a far UV (UV-B) wavelength range, or a deep UV (UV-C) wavelength range. A wavelength range can be determined by a composition ratio of an active layer. For example, the light within the UV-A wavelength range can have wavelengths ranging from 320 nanometers (nm) to 420 nm, the light within the UV-B wavelength range can have wavelengths ranging from 280 nm to 320 nm, and the light within the UV-C wavelength range can have wavelengths ranging from 100 nm to 280 nm.

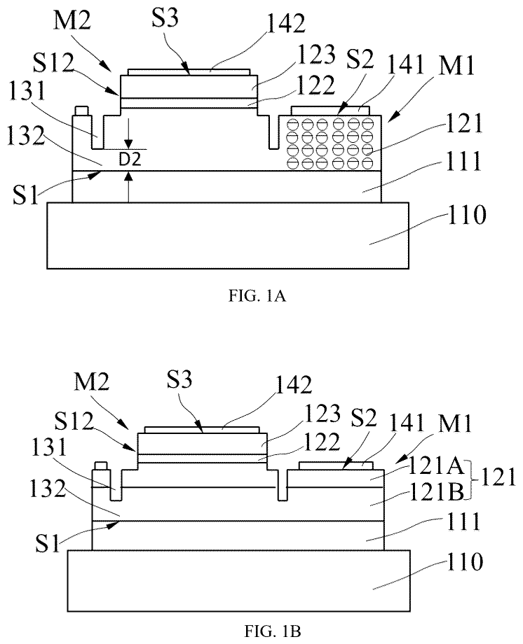

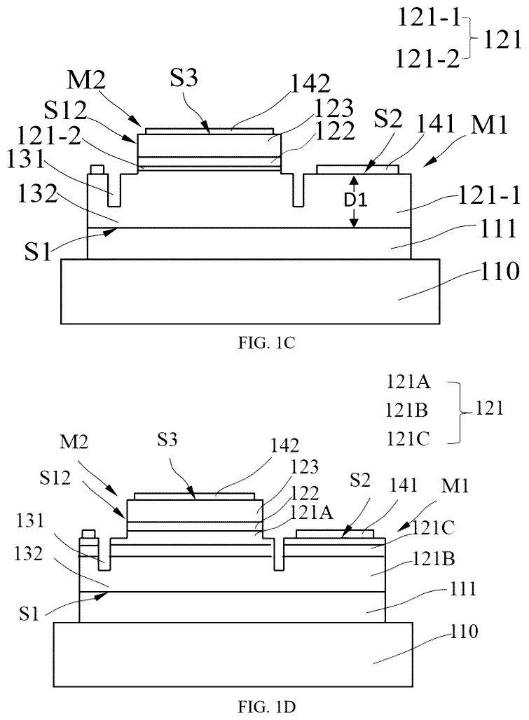

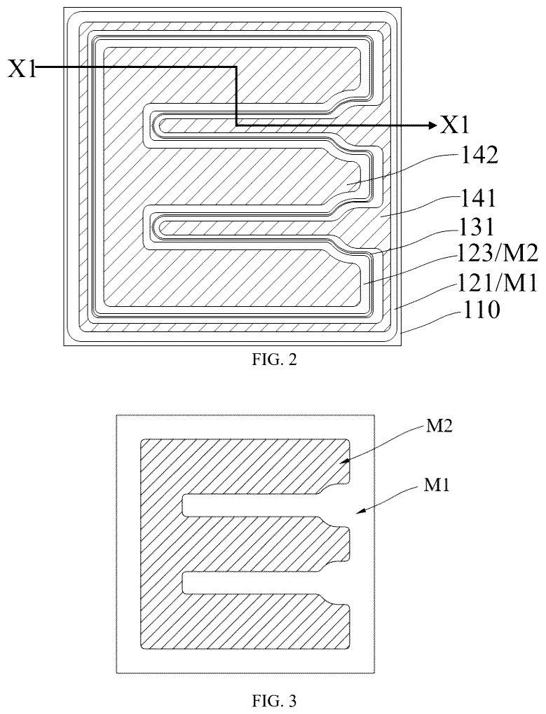

FIGS. 1A-1D and FIG. 2 illustrate schematic structural views of light-emitting diodes according to illustrated embodiments of the disclosure, where FIG. 2 is a top view, and FIGS. 1A-1D are longitudinal cross-sectional views taken along a line X1-X1 of FIG. 2. The light-emitting diode includes a substrate 110, a semiconductor layer sequence disposed on the substrate 110 and electrodes 141 and 142 (i.e., a first electrode 141 and a second electrode 142). The semiconductor layer sequence is provided with a first mesa M1, a second mesa M2 and a current blocking structure 131 located on the first mesa M1.

Specifically, the substrate 110 is configured to support the semiconductor layer sequence. For example, the substrate 110 is a sapphire substrate, and can also be a growth substrate capable of forming a film of a group-III-nitride semiconductor. Specifically, a layer of aluminum nitride is formed on an upper surface of the substrate 110 as a bottom layer 111 (i.e., an aluminum nitride bottom layer), the bottom layer 111 is in direct contact with a surface of the substrate 110. A thickness of the bottom layer 111 can be between 10 nm and 4 micrometers (μm). In some specific embodiments, a series of hole structures are formed in the bottom layer 111, which are beneficial for relieving stress of the semiconductor layer sequence. The series of holes are specifically a series of elongated holes extending along a thickness of the aluminum nitride, and a depth of each of the holes, for example, is 0.5 μm to 1.5 μm.

The semiconductor layer sequence is formed on the bottom layer 111, sequentially including a first semiconductor layer 121, a second semiconductor layer 123 and an active layer 122 located between the first semiconductor layer 121 and the second semiconductor layer 123. For example, the first semiconductor layer 121 is an n-type layer, and the second semiconductor layer 123 is a p-type layer, which can also be reversed. In a specific embodiment, for example, the first semiconductor layer 121 is an n-type AlGaN layer, the active layer 122 is a layer that emits light at a specific wavelength, including a well layer and a barrier layer, the second semiconductor layer 123 is a p-type AlGaN layer or a p-type GaN layer, or a layer formed by sequentially stacking a p-type AlGaN layer and a p-type GaN layer.

The partial removal of certain areas of the semiconductor layer sequence, including the second semiconductor layer 123 and the active layer 122, exposes the first semiconductor layer 121 to form one or more first mesas M1 and second mesas M2, as shown in FIGS. 1A-1D and FIG. 3. The first mesa M1 is configured to form the first electrode 141, and the second mesa M2 is located in the first semiconductor layer 121, which includes the active layer 122 and the second semiconductor layer 123. In this embodiment, multiple first mesas M1 that surround the second mesa M2 are formed. A distribution of the multiple first mesas M1 is not limited to that shown in FIG. 3 and can be designed according to an actual size and a shape of a chip. The multiple first mesas M1 can be connected together or separated from each other. In a top view of the semiconductor layer sequence shown in FIG. 3, the first mesas M1 surround the second mesa M2. In other embodiments, the semiconductor layer sequence can also have multiple first mesas M1 that are exposed to each other, distributed inside the second mesa M2, and the multiple first mesas M1 may have one or more finger-like shapes. The first electrode 141 is formed on the multiple first mesas M1 and forms an ohmic contact with the first semiconductor layer 121, and the second electrode 142 is formed on the second semiconductor layer 123 and forms an ohmic contact with the second semiconductor layer 123.

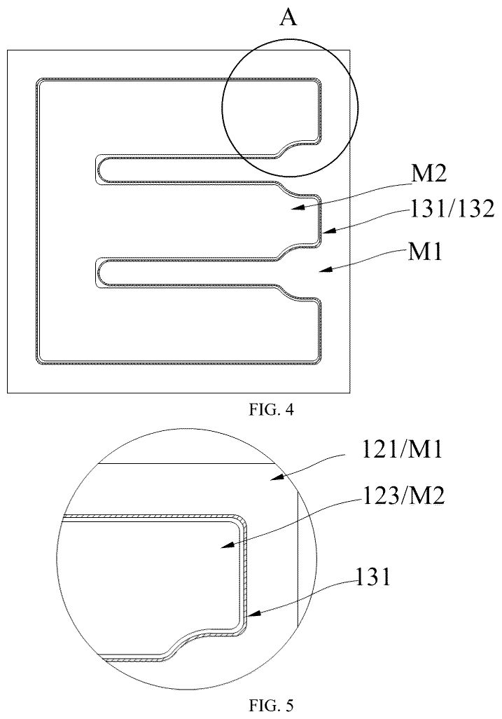

The first mesa M1 has the current blocking structure 131 adjacent to the second mesa M2 and a current conduction portion 132 located below the current blocking structure 131, as shown in FIGS. 1A-1D and FIG. 4. The current blocking structure 131 can be formed by etching to create a groove, or can be formed by injecting ions to render an area highly resistive. By setting the current blocking structure 131 between the first mesa M1 and the second mesa M2, carriers injected from a second surface S2 of the first mesa M1 are blocked from flowing directly from an area of the first mesa M1 adjacent to the second surface S2 to the second mesa M2, which promotes the carries to migrate downward and expand, and then flow into the second mesa M2 through the current conduction portion 132. Specifically, the first semiconductor layer 121 is provided with a first surface S1 adjacent to the substrate 110, and the first mesa M1 is provided with the second surface S2 facing away from the first surface S1. A distance D1 between the second surface S2 and the first surface S1 is controlled to be greater than or equal to half of a thickness of the first semiconductor layer 121, which makes that when the carriers are injected into the light-emitting diode, the carriers do not directly migrate towards the active layer 122 of the second mesa M2, but are instead blocked by the current blocking structure 131, and then fully expand downwards, thereby mobilizing carriers below to participate in a movement, allowing more carriers in the n-type AlGaN semiconductor layer to be effectively utilized, thereby enhancing carrier injection efficiency. Specifically, the distance DI can be between 60% and 95% of the thickness of the first semiconductor layer 121. In a specific embodiment, the thickness of the first semiconductor layer 121 can be 1.5 μm to 3.5 μm, and the distance D1 can be 1 μm to 3 μm, such as 1.2 μm, 1.8 μm, 2 μm, 2.5 μm, or 3 μm. Further, a distance between the second surface S2 and the current conduction portion 132 is specifically greater than 500 nm, which allows the carries injected through the second surface S2 to fully expand before flowing into the first semiconductor layer 121 below the second mesa M2 through the current conduction portion 132, and finally to uniformly flow into the active layer 122 of the second mesa M2.

Referring to FIGS. 1A-1D and FIG. 5, where FIG. 5 illustrates a partial enlarged view of region A in FIG. 4, the first mesa M1 is provided with the second surface S2, and the second mesa M2 is provided with a third surface S3 facing away from the second surface S2. The semiconductor layer sequence is provided with a side wall S12 connecting the second surface S2 and the third surface S3, and a distance is provided between the current blocking structure 131 and the side wall S12 to avoid damaging a structure of the second mesa M2 during a formation of the current blocking structure 131. Specifically, the distance between the current blocking structure 131 and the side wall S12 is greater than 1 μm, for example, the distance can be 1 μm to 10 μm. In this embodiment, the current blocking structure 131 is a slender groove structure. On the one hand, the current blocking structure 131 can block the carriers from flowing directly flow from the area of the first mesa M1 adjacent the second surface S2 to the active layer 122 of the second mesa M2, and on the other hand, the current blocking structure 131 can serve as a light extraction structure to enhance light extraction efficiency of the light-emitting diode.

A height D2 of the current conduction portion 132 in a thickness direction of the semiconductor layer sequence is specifically ⅕ to ½ of the thickness of the first semiconductor layer 121. When the height D2 of the current conduction portion 132 is too small, it will cause a congestion phenomenon when the carriers reach the current conduction portion 132, thereby reducing injection of the carriers. When the height D2 of the current conduction portion 132 in the thickness direction is too large, the current conduction portion 132 is close to the second surface S2 of the first mesa M1, which is not conducive to the expansion of carriers. In some embodiments, a doping concentration of the current conduction portion 132 is greater than 5×10¹⁸/cm³, and the height D2 of the current conduction portion 132 in the thickness direction can be 0.2 μm to 1 μm, such as 0.3 μm to 0.6 μm.

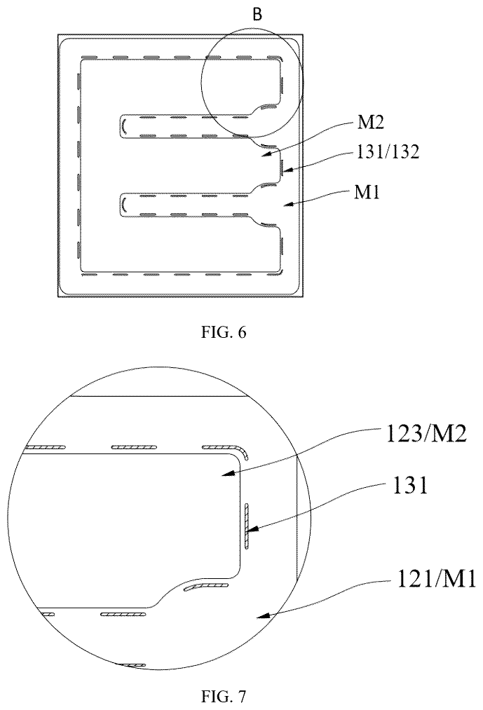

The height D2 of the current conduction portion 132 can be adjusted by according to a distribution of the current blocking structure 131, thereby regulating efficiency of carrier injection into the first semiconductor layer 121. For example, as shown in FIG. 4, the current blocking structure 131 forms a fully blocking between the first mesa M1 and the second mesa M2, at this time, the height D2 of the current conduction portion 132 is specifically 400 nm to 800 nm, such as 500 nm or 600 nm. In other embodiments, the current blocking structure 131 can also be discontinuously distributed, as shown in FIGS. 6 and 7 (where FIG. 7 illustrates a partial enlarged view of region B in FIG. 6). In these embodiments, some of the carriers injected through the first mesa M1 can directly migrate towards the second semiconductor layer 123 of the second mesa M2 through gaps between the current blocking structure 131, therefore reducing the height D2 of the current conduction portion 132, at this time the height D2 can be 200 nm to 500 nm, such as 300 nm.

In some embodiments, as shown in FIG. 1B, the first semiconductor layer 121 is an n-type doped layer, which can include a highly doped layer 121-1 (i.e., a first doped layer) and a low doped layer 121-2 (i.e., a second doped layer). The low doped layer 121-2 is located between the active layer 122 and the high doped layer 121-1, thereby effectively confining the carriers within the active layer 122. A doping concentration of the low doped layer 121-2 is specifically less than 1×10¹⁸/cm³, for example, it can range from 2×10¹⁷/cm³ to 1×10¹⁸/cm³, and a thickness of the low doped layer 121-2 can be 20 nm to 100 nm. A doping concentration of the high doped layer 121-1 is generally greater than 5×10¹⁸/cm³, specifically greater than 1×10¹⁹/cm³, and the second surface S2 of the first mesa M1 is specifically located in the high doped layer 121-1, which is beneficial for forming the first electrode 141 with a good ohmic contact on the second surface S2.

In some embodiments, as shown in FIG. 1C, the first semiconductor layer 121 is the n-type doped layer, which can include a first sub-layer 121A with a first doping concentration and a second sub-layer 121B with a second doping concentration. The first sub-layer 121A is located between the second sub-layer 121B and the active layer 122, and the first doping concentration is greater than the second doping concentration. In a specific embodiment, the first doping concentration is specifically greater than 1.2 times the second doping concentration, for example, it can range from 1.2 times to 2 times. The first sub-layer 121A, serving as a contact layer, has a higher doping concentration that allows for better ohmic contact with the electrode, thereby reducing a voltage of a device. The second sub-layer 121B, serving as a carrier injection and expansion layer, requires a relatively large thickness (specifically greater than 1 μm). Thus, the second doping concentration of the second sub-layer 121B is set slightly lower than the first doping concentration of the first sub-layer 121A, which helps to avoid the decrease in crystal quality of the first semiconductor layer 121 due to high doping and also facilitates lateral diffusion of the carriers. In a specific embodiment, the first doping concentration can be greater than 1×10¹⁹/cm³, for example, it can be 1×10¹⁹/cm³ to 5×10¹⁹/cm³, and the second doping concentration is greater than 5×10¹⁸/cm³, for example, it can be 5×10¹⁸/cm³ to 3×10¹⁹/cm³, which can better balance crystal quality of the first semiconductor layer 121 and the expansion capability of the carriers, and the thickness of the second sub-layer 121B is specifically greater than 1 μm. Specifically, the second surface S2 of the first mesa M1 is located in the first sub-layer 121A, and by appropriately increasing the first doping concentration of the first sub-layer 121A, it is beneficial to form the first electrode 141 with the good ohmic contact on the second surface S2. The current conduction portion 132 is located in the second sub-layer 121B, which can better facilitate current expansion to thereby uniformly flow to the first semiconductor layer 121 below the second mesa M2.

The first electrode 141 is directly formed in contact with the first mesa M1 and forms the ohmic contact with the second surface S2 of the first mesa M1. The first electrode 141 is selected from one or more of chromium (Cr), platinum (Pt), aurum (Au), nickel (Ni), titanium (Ti), aluminum (Al). Due to a high Al component of the first semiconductor layer 121, the first electrode 141 needs to be fused at a high temperature to form an alloy after being deposited on the first mesa M1, thereby forming the good ohmic contact with the first semiconductor layer 121. For example, the first electrode 141 can be Ti—Al—Au alloy, Ti—Al—Ni—Au alloy, Cr—Al—Ti—Au alloy, Ti—Al—Au—Pt alloy, etc.

The second electrode 142 is formed in contact with the surface S3 of the second mesa M2 and forms the ohmic contact with the second semiconductor layer 123. Specifically, a material of the second electrode 142 can be an oxide transparent conductive material or a metal alloy such as NiAu, NiAg, NiRh, and a thickness of the second electrode 142 is specifically less than 30 nm to minimize a light absorption rate of the second electrode 142. In a specific embodiment, the active layer 122 emits light with a wavelength of less than 280 nm, the second electrode 142 is made of indium tin oxide (ITO) with a thickness of 5 nm to 20 nm, for example, the thickness of the second electrode 142 can be 10 nm to 15 nm, and the absorption rate of the ITO layer (i.e., the second electrode 142) for the light emitted by the active layer 122 can be reduced to within 40%.

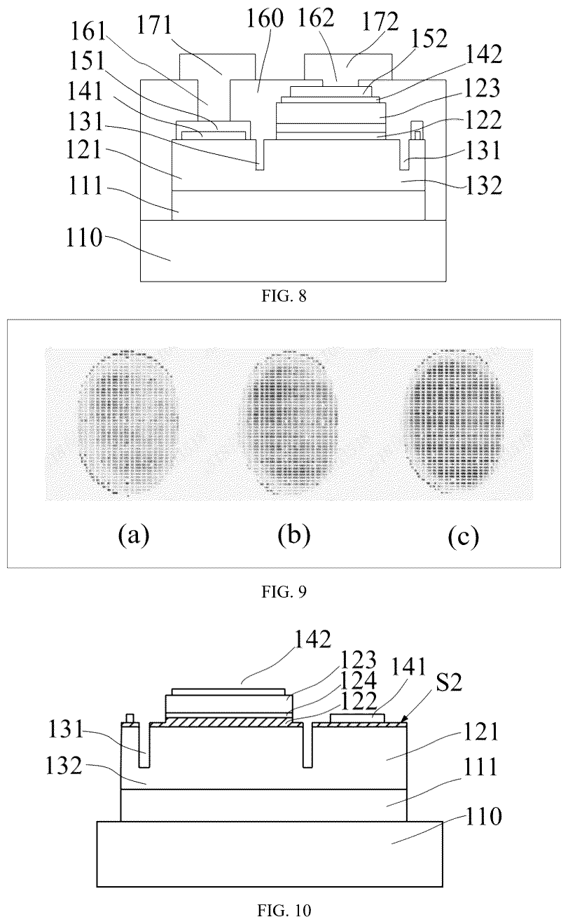

In some embodiments, the light-emitting diode is a flip-chip light-emitting diode, which may further include a first connecting electrode 151, a second connecting electrode 152, an insulating layer 160, a first pad electrode 171, and a second pad electrode 172, as shown in FIG. 8. The first connecting electrode 151 is formed on the first electrode 141, and the second connecting electrode 152 is formed on the second electrode 142. The connecting electrodes are specifically multi-layer metal stacks, for example, an adhesion layer and a conductive layer sequentially deposited on the connecting electrodes. The adhesion layer can be a Cr metal layer with a thickness of usually 1 nm to 10 nm, and the conductive layer can be an Al metal layer with a thickness of greater than 100 nm, for example, the thickness of the conductive layer can be 200 nm to 500 nm. On the one hand, Al has a good conductivity, and on the other hand, Al has a high reflectivity to ultraviolet light. Specifically, the reflectivity of the conductive layer to the light emitted by the active layer 122 is greater than 70%. Further, a stress-buffering layer is specifically inserted inside the conductive layer, such as an Al/Ti alternating layer. Additionally, an etch stop layer Pt and an adhesion layer Ti can be formed on the conductive layer. Specifically, a first metal flow expansion layer is formed on the first electrode 141, as shown in FIG. 8. The first connecting electrode 151 can be formed in a same process as a second metal expansion layer, having a same metal stack structure. Specifically, the first connecting electrode 151 completely covers the first electrode 141, which can increase a height of a mesa area and protect the first electrode 141.

The insulating layer 160 is formed on the first connecting electrode 151 and the second connecting electrode 152 and on sides of the semiconductor layer sequence and the first mesa M1, which insulates the first connecting electrode 151 and the second connecting electrode 152. The insulating layer 160 is defined with openings (i.e., a first opening 161 and a second opening 162) to expose the first connecting electrode 151 and the second connecting electrode 152. A material of the insulating layer 160 includes a non-conductive material, and the non-conductive material is specifically an inorganic material or a dielectric material. The inorganic material includes silica gel or glass, and the dielectric material includes aluminum oxide, silicon nitride, silicon dioxide, titanium oxide, or magnesium fluoride. For example, the insulating layer 160 can be silicon dioxide, silicon nitride, titanium oxide, tantalum oxide, niobium oxide, barium titanate, or a combination thereof, which may, for example, be a Bragg reflector (DBR) formed by repeated stacking of two materials. In some embodiments, the insulating layer 160 is specifically a reflective insulating layer. As shown in FIG. 8, the light-emitting diode has a larger area mesa structure, and the second connecting electrode 152 is only partially formed on the second electrode 142. Therefore, by setting the insulating layer 160 as a high-reflectivity structure, light extraction efficiency of the light-emitting diode can be effectively improved.

The first pad electrode 171 and the second pad electrode 172 are located on the insulating layer 160 and are respectively electrically connected to the first connecting electrode 151 and the second connecting electrode 152 through the first opening 161 and the second opening 162. The first pad electrode 171 and the second pad electrode 172 can be formed together in a same process using a same material and can therefore have a same layer structure. The materials of the first pad electrode 171 and the second pad electrode 172 can be selected from one or more of Cr, Pt, Au, Ni, Ti, Al, Au, Sn. Specifically, a portion of the first pad electrode 171 is located on the first mesa M1, another portion of the first pad electrode 171 is located on the second mesa M2, and the second pad electrode 172 is located on the second mesa M2.

In the light emitting diode disclosed in the above illustrated embodiments, the carrier injection efficiency of the n-type AlGaN semiconductor layer can be improved, thereby enhancing the luminous efficiency. The light output power of different embodiments is compared below. First, three different structures of samples a, b, and c are fabricated on a same epitaxial wafer, having a same mesa distribution (refer to FIG. 3 for a distribution diagram). The sample a is served as a comparative example (without current blocking structure 131), the sample b is designed to etch a series of spaced-apart grooves at a position of the first mesa M1 adjacent to the second mesa M2 according to FIG. 6 as the current blocking structure 131, and sample c is designed to etch continuous grooves at the position of the first mesa M1 adjacent to the second mesa M2 according to FIG. 4 as the current blocking structure 131. After fabricating various electrode layers and cutting for LED chips, the light output power is tested. FIG. 9 illustrates the light output power of the LEDs for the three samples, where (a) illustrates the light output power distribution map (also referred to as LOP Mapping) for the comparative example, (b) illustrates the light output power distribution map for the sample b, and (c) illustrates the light output power distribution map for the sample c. A darkness of a grayscale indicates brightness, with darker shade indicating greater brightness. It can be seen from the FIG. 9 that compared with the sample a, the light output power of the sample b has been improved, and the light output power of the sample c has been significantly improved.

In a modified embodiment, as shown in FIG. 1D, the first semiconductor layer 121 can sequentially include a first sub-layer 121A with a first doping concentration, a third sub-layer 121C with a third doping concentration, and a second sub-layer 121B with a second doping concentration. The second sub-layer 121B is located between the third sub-layer 121C and the substrate 110, and the first sub-layer 121A is located between the third sub-layer 121C and the active layer 122. In the embodiment, the third doping concentration is less than the first doping concentration and the second doping concentration. The first electrode 141 is in direct contact with the first sub-layer 121A, and the current conduction portion 132 is located in the second sub-layer 121B. Specifically, the first doping concentration and the second doping concentration can be greater than 1×10¹⁹/cm³, for example, ranging from 1×10¹⁹/cm³ to 5×10¹⁹/cm³, the third doping concentration is greater than 5×10¹⁸/cm³, for example, ranging from 5×10¹⁸/cm³ to 3×10¹⁹/cm³. In the embodiment, the first sub-layer 121A, with a higher doping concentration, is more conducive to forming a good ohmic contact with the first electrode 141. The third sub-layer 121C, located between the first electrode 141 and the current conduction portion 132, requires a sufficient thickness (specifically greater than 1 μm) for the expansion of carriers, thus the third sub-layer 121C having a lower doping concentration can better balance the crystal quality of the first semiconductor layer 121 and the expansion capability of the carriers. The second sub-layer 121B, with a higher doping concentration, can promote the rapid migration of carriers through the current conduction portion 132 to the second mesa M2.

FIG. 10 illustrates a schematic structural diagram of a light-emitting diode disclosed in another illustrated embodiment of the disclosure, and a top view of the light-emitting diode can be referred to FIG. 2.

Referring to FIG. 10, in the embodiment, a fully blocking current blocking structure 131 is formed in the first mesa M1 of the light-emitting diode (as shown in FIG. 4). The first mesa M1 of the light-emitting diode includes the first semiconductor layer 121 entirely and a portion of the active layer 122, that is, the second surface S2 (i.e., an upper surface) of the first mesa M1 is located in the active layer 122. Specifically, the active layer 122 can have n-type doping, such as Si doping, and a doping concentration of the active layer 122 is greater than 1×10¹⁸/cm³, specifically between 1×10¹⁸/cm³ and 1×10¹⁹/cm³, for example, it can be 2×10¹⁸/cm³ or 5×10¹⁸/cm³, etc.

In the embodiment, by appropriately adding the n-type doping to the active layer 122, on the one hand, it is beneficial to increase an electron concentration of the active layer 122 and thus improve internal quantum efficiency, and on the other hand, the active layer 122 can used to directly fabricate the first electrode 141 with the good ohmic contact. In a specific embodiment, a bandgap of the active layer 122 is lower than a bandgap of the first semiconductor layer 121, which is more conducive to forming the good ohmic contact for the first electrode 141 on the second surface S2 of the first mesa M1.

In a specific embodiment, the semiconductor layer sequence may include a confinement layer 124, which is disposed between the active layer 122 and the second semiconductor layer 123. The confinement layer 124 has a higher Al component and low-doped or undoped, and a thickness of the confinement layer 124 is less than 50 nm, which can confine diffusion of doping elements from the second semiconductor layer 123 to the active layer 122, thereby enhancing optoelectronic performance of the light-emitting diode.

In the embodiment, the fully blocking current blocking structure 131 is formed between the first mesa M1 and the second mesa M2 to isolate the active layer 122 on the first mesa M1 from the active layer 122 on the second mesa M2, thereby increasing a distance between the first mesa M1 and the first surface S1 of the first semiconductor layer 121, and further enhancing the expansion and carrier injection efficiency of the first semiconductor layer 121.

FIG. 11 illustrates a schematic structural diagram of a light-emitting diode disclosed in still another illustrated embodiment of the disclosure, and a top view the light-emitting diode can be referred to in FIG. 2.

Referring to FIG. 11, in the embodiment, the fully blocking current blocking structure 131 is formed in the first mesa M1 of the light-emitting diode (as shown in FIG. 4). The first mesa M1 of the light-emitting diode includes the entire first semiconductor layer 121, the entire active layer 122, and a portion of the second semiconductor layer 123, that is, the second surface S2 of the first mesa M1 is located in the second semiconductor layer 123. Specifically, the second semiconductor layer 123 is a p-type doped layer, which can include a first high doped layer 123A, an electron blocking layer 123B, and a second high doped layer 123C sequentially stacked in that order. The first high doped layer 123A is located between the electron blocking layer 123B and the active layer 122, serving as an ohmic contact layer and a hole injection layer of the first electrode 141. A doping concentration of the first high doped layer 123 A is specifically greater than 1×10¹⁹/cm³, for example, it can range from 1×10¹⁹/cm³ to 5×10¹⁹/cm³. A doping concentration of the electron blocking layer 123B is greater than 1×10¹⁷/cm³, for example, it can range from 1×10¹⁸/cm³ to 1×10¹⁹/cm³. A doping concentration of the second high doped layer 123C is specifically greater than 5×10¹⁹/cm³, for example, it can range from 5×10¹⁹/cm³ to 5×10²¹/cm³.

A bandgap of the electron blocking layer 123B is higher than that of the first high doped layer 123A and the second high doped layer 123C. Therefore, the second surface S2 of the first mesa M1 is controlled to be below the electron blocking layer 123B to prevent the carriers injected from the second surface S2 of the first mesa M1 from being blocked by the electron blocking layer 123B, thereby reducing the injection efficiency. In a specific embodiment, a height difference between the second surface S2 of the first mesa M1 and the third surface S3 of the second mesa M2 is specifically greater than 50 nm and less than or equal to 500 nm, for example, the height difference can be greater than 50 nm and less than 200 nm or greater than or equal to 200 nm and less than or equal to 500 nm.

In the illustrated embodiment, the fully blocking current blocking structure 131 is formed between the first mesa M1 and the second mesa M2 to separate the semiconductor layer sequence on the first mesa M1 from the semiconductor sequence on the second mesa M2, which allows the upper surface of the first mesa M1 to be elevated to the second semiconductor layer 123. By inserting the first high doped layer 123A on a side of the second semiconductor layer 123 close to the active layer 122, the first high doped layer 123A in the first mesa M1 served as an electrode contact surface, can used to directly fabricate the first electrode 141 with the good ohmic contact. The first high doped layer 123A on the second mesa M2 served as a hole injection layer, can improve hole injection efficiency of the second semiconductor layer 123.

In the embodiment, since the first electrode 141 is directly formed on the first high doped layer 123A of the second semiconductor layer 123, a same material as the second electrode 142 can be used to solve a problem of forming an ohmic contact in the n-type AlGaN semiconductor layer and reduce a height difference between the first mesa M1 and the second mesa M2. When fabricating pad electrodes on both the first mesa M1 and the second mesa M2, an overall product exhibits better push force and reliability under a same condition.

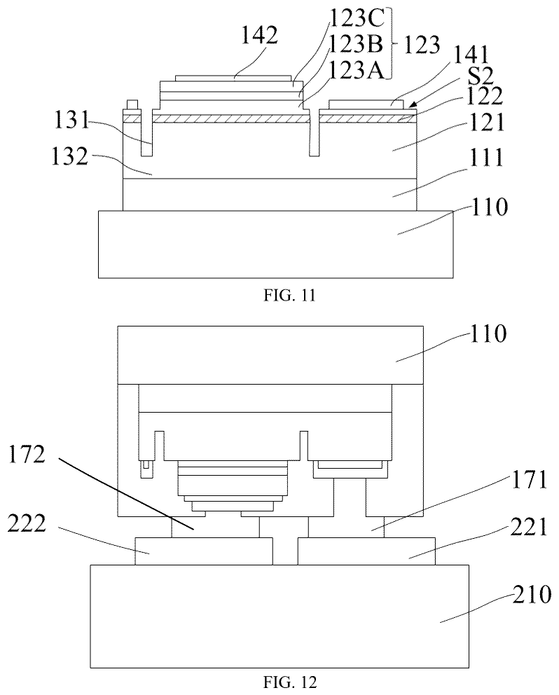

Referring to FIG. 12, a light-emitting device is disclosed in an embodiment. The light-emitting device uses the light-emitting diode in the abovementioned embodiments as a core chip, and the light-emitting diode is fixed on a circuit board 210. The circuit board 210 is provided with a first conductive layer 221 and a second conductive layer 222, and the first conductive layer 221 and the second conductive layer 222 are isolated from each other. The first pad electrode 171 of the light-emitting diode is disposed on the first conductive layer 221 and is electrically connected to the first conductive layer 221, and the second pad electrode 172 of the light-emitting diode is disposed on the second conductive layer 222 and is electrically connected to the second conductive layer 222.

In the embodiment, increasing a distance between the upper surface of the first mesa M1 and a lower surface of the first semiconductor layer 121 can improve the carrier injection efficiency of the n-type AlGaN semiconductor layer, thereby enhancing the luminous efficiency of the light-emitting device. Further, reducing the height difference between the first mesa M1 and the second mesa M2 can increase the push force of electrodes when pad electrodes are fabricated on the first mesa M1 and the second mesa M2.

In the embodiment, the light-emitting diode and the circuit board 210 are integrated as a whole. Due to the close area of the first pad electrode 171 and the second pad electrode 172, it is beneficial for the overall product to have better push force and reliability under the same condition.

What is claimed is:

1. A light-emitting diode, comprising:
a semiconductor layer sequence, wherein the semiconductor layer sequence comprises a first semiconductor layer with a first conductive type, a second semiconductor layer with a second conductive type different from the first conductive type, and an active layer disposed between the first semiconductor layer and the second semiconductor layer; the semiconductor layer sequence further comprises a first mesa and a second mesa located above the first mesa, wherein the first mesa has a current blocking structure adjacent to the second mesa and a current conduction portion located below the current blocking structure, and the second mesa functions as a light-emitting mesa;
a first electrode, formed on the first mesa, and electrically connected to the first semiconductor layer; and
a second electrode, formed on the second mesa, and electrically connected to the second semiconductor layer;
wherein the first semiconductor layer is an n-type doped aluminum gallium nitride (AlGaN) semiconductor layer and has a first surface facing away from the active layer; and the first mesa is provided with a second surface facing away from the first surface, a distance between the second surface and the first surface is greater than or equal to a half of a thickness of the first semiconductor layer; and
wherein the current conduction portion has a height in a thickness direction of the semiconductor layer sequence in a range of ⅕ to ½ of the thickness of the first semiconductor layer.

2. The light-emitting diode as claimed in claim 1, wherein the second mesa is provided with a third surface facing away from the second surface, the semiconductor layer sequence is provided with a side wall connecting the second surface and the third surface, and a distance is provided between the current blocking structure and the side wall.

3. The light-emitting diode as claimed in claim 1, wherein a distance between the second surface and the current conduction portion is greater than 500 nanometers (nm).

4. The light-emitting diode as claimed in claim 1, wherein the current blocking structure is distributed continuously or discontinuously.

5. The light-emitting diode as claimed in claim 2, wherein the distance between the current blocking structure and the side wall is in a range of 1 micrometer (μm) to 10 μm.

6. The light-emitting diode as claimed in claim 1, wherein the active layer is an n-type doped AlGaN semiconductor layer, a doping concentration of the active layer is greater than 1×10¹⁸/cm³, and a bandgap of the active layer is lower than that of the first semiconductor layer.

7. The light-emitting diode as claimed in claim 1, wherein the second semiconductor layer comprises a p-type AlGaN semiconductor layer and a p-type gallium nitride (GaN) layer sequentially stacked in that order.

8. The light-emitting diode as claimed in claim 1, wherein the second semiconductor layer comprises a first high doped layer, an electron blocking layer, and a second high doped layer sequentially stacked in that order, a doping concentration of the first high doped layer is greater than 1×10¹⁹/cm³, a doping concentration of the electron blocking layer is greater than 1×10¹⁷/cm³, and a doping concentration of the second high doped layer is greater than 5×10¹⁹/cm³.

9. The light-emitting diode as claimed in claim 8, wherein the second surface of the first mesa is located in the first high doped layer.

10. The light-emitting diode as claimed in claim 1, wherein the first semiconductor layer comprises a first sub-layer with a first doping concentration and a second sub-layer with a second doping concentration, the first doping concentration is greater than the second doping concentration, and the first electrode is in direct contact with the first sub-layer.

11. The light-emitting diode as claimed in claim 1, wherein the first semiconductor layer comprises a first doped layer with a first doping concentration and a second doped layer with a second doping concentration, the first electrode is in direct contact with the first doped layer, and the second doped layer is located between the first doped layer and the active layer; the first doping concentration is greater than 1×10¹⁹/cm³, and the second doping concentration is less than 1×10¹⁸/cm³.

12. The light-emitting diode as claimed in claim 1, wherein the semiconductor layer sequence further comprises a confinement layer disposed between the active layer and the second semiconductor layer, and a doping concentration of the confinement layer is less than 1×10¹⁸/cm³.

13. The light-emitting diode as claimed in claim 1, wherein the light-emitting diode further comprises a first connecting electrode and a second connecting electrode, the first connecting electrode is electrically connected to the first electrode, and the second connecting electrode is electrically connected to the second electrode.

14. The light-emitting diode as claimed in claim 13, wherein the light-emitting diode further comprises an insulating layer, a first pad electrode, and a second pad electrode; the insulating layer is formed on the first pad electrode and the second pad electrode, the insulating layer is defined with a first opening and a second opening, the first opening exposes the first connecting electrode, and the second opening exposes the second connecting electrode; the first pad electrode is electrically connected to the first connecting electrode through the first opening, and the second pad electrode is electrically connected to the second connecting electrode through the second opening.

15. The light-emitting diode as claimed in claim 1, wherein the first semiconductor layer comprises a first sub-layer with a first doping concentration and a second sub-layer with a second doping concentration, the first doping concentration is greater than the second doping concentration, the second surface is located on the first sub-layer, the first electrode is in direct contact with the first sub-layer, and the current conduction portion is located in the second sub-layer.

16. The light-emitting diode as claimed in claim 15, wherein the first semiconductor layer further comprises a third sub-layer with a third doping concentration, the third sub-layer is located between the first sub-layer and the second sub-layer, and the third doping concentration is greater than 5×10¹⁸/cm³.

17. The light-emitting diode as claimed in claim 10, wherein the first doping concentration is greater than 1.2 times the second doping concentration, and the first doping concentration is greater than 1×10¹⁹/cm³.

18. The light-emitting diode as claimed in claim 15, wherein the semiconductor layer sequence is provided with a side wall connecting the first mesa and the second mesa, and a distance is provided between the current blocking structure and the side wall.

19. The light-emitting diode as claimed in claim 15, wherein the height of the current conduction portion in the thickness direction of the semiconductor layer sequence is greater than 200 nm.

20. A light-emitting device, wherein the light-emitting device uses the light-emitting diode as claimed in claim 1.
